(19) United States
(12) Patent Application Publication
(10) Pub. No.: US 2020/0052106 A1
(43) Pub. Date: Feb. 13, 2020

(54) METHODS, APPARATUS, AND SYSTEM TO CONTROL GATE HEIGHT AND CAP THICKNESS ACROSS MULTIPLE GATES

(71) Applicant: GLOBALFOUNDRIES INC., Grand Cayman (KY)

(72) Inventors: Laertis Economikos, Wappingers Falls, NY (US); Hui Zang, Guilderland, NY (US); Ruilong Xie, Niskayuna, NY (US); Neal Makela, Saratoga Springs, NY (US); Pei Liu, Saratoga Springs, NY (US); Jiehui Shu, Clifton Park, NY (US); Chih-chiang Chang, Clifton Park, NY (US)

(73) Assignee: GLOBALFOUNDRIES INC., GRAND CAYMAN (KY)

(21) Appl. No.: 16/101,162

(22) Filed: Aug. 10, 2018

(51) Int. Cl. H01L 29/78; H01L 29/66; H01L 29/49; H01L 21/768; H01L 21/8234; H01L 21/28

(52) U.S. Cl. CPC H01L 29/785; H01L 29/66795; H01L 29/4975; H01L 21/823431; H01L 21/76832; H01L 21/823468; H01L 21/28088; H01L 29/6656

(57) ABSTRACT

At least one method, apparatus, and system providing semiconductor devices comprising a first gate having a first width and comprising a first work function metal (WFM); a first liner disposed over the first WFM; a first gate metal having a first height; and a first pinch-off spacer over the first WFM, the first liner, and the first gate metal to above the first height; and a second gate having a second width greater than the first width, and comprising a second WFM; a second liner disposed over the second WFM; a second gate metal having substantially the first height; and a first conformal spacer over the second WFM and the second liner.

### BACKGROUND OF THE INVENTION

### Field of the Invention

Generally, the present disclosure relates to the manufacture of sophisticated semiconductor devices, and more specifically, to semiconductor devices having gates of varying width but with substantially the same gate metal heights.

### Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a device that typically includes a source region, a drain region, a channel region that is positioned between the source region and the drain region, and a gate electrode positioned above the channel region.

In contrast to a planar FET, which has a planar structure, there are so-called 3D devices, such as an illustrative finFET device, which is a 3-dimensional structure. More specifically, in a finFET, a generally vertically positioned, fin-shaped active area is formed and a gate electrode encloses both of the sides and the upper surface of the fin-shaped active area to form a trigate structure so as to use a channel having a 3-dimensional structure instead of a planar structure. In some cases, an insulating cap layer, e.g., silicon nitride, is positioned at the top of the fin and the finFET device only has a dual-gate structure.

In the continuing effort to increase the capabilities of semiconductor devices, designers have created semiconductor devices having varying gate widths among the gates of a single device. However, changing the widths of gates may lead to variations in the height of gate metal between narrower and wider gates, with wider gates typically having undesirably low gate metal heights relative to narrower gates.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus, and systems for forming semiconductor devices comprising gates of different widths with substantially uniform gate metal heights.

In one embodiment, the present disclosure relates to a method comprising forming a first gate having a first width and comprising a first work function metal; a first liner disposed over the first liner; a first gate metal over the first liner and having a first height above the height of the first work function metal; and a first spacer on the sides of the first gate and having a first spacer height greater than the first height; forming a second gate having a second width and comprising a second work function metal; a second liner disposed over the second liner; and a second gate metal over the second liner and having a second height, wherein the first width is less than the second width and the first height is greater than the second height; and a second spacer on the sides of the second gate and having a second spacer height greater than the second height; filling a first region between the first spacer on the sides of the first gate and above the first gate metal with a third spacer material up to at least the first spacer height; depositing conformally the third spacer material in a second region between the second spacer on the sides of the second gate, and on a top of the second gate metal up to a third spacer material height below the second spacer height; removing the third spacer material from the top of the second gate metal, wherein the first gate metal remains covered by the third spacer material; adding metal to the second gate metal, thereby raising the top of the second gate metal to about the first height.

In one embodiment, the present disclosure relates to a semiconductor device, comprising a first gate having a first width and comprising a first work function metal (WFM); a first liner disposed over the first WFM; a first gate metal over the first liner and having a first height above the height of the first work function metal; a first spacer on the sides of the first gate and having a first spacer height greater than the first height; a first pinch-off spacer over the first WFM, the first liner, and the first gate metal to above the first height and below the first spacer height; and a second gate having a second width greater than the first width, and comprising a second WFM; a second liner disposed over the second WFM; a second gate metal over the second liner and having substantially the first height; a second spacer on the sides of the second gate and having a second spacer height greater than the first height; and a first conformal spacer over the second WFM and the second liner.

In one embodiment, the present disclosure relates to a system comprising a semiconductor device processing system to manufacture a semiconductor device; and a processing controller operatively coupled to the semiconductor device processing system, the processing controller configured to control an operation of the semiconductor device processing system; wherein the semiconductor device processing system is adapted to implement a method referred to above.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized, simplified cross-sectional view of a semiconductor device 100 after a first stage of manufacture, in accordance with embodiments herein;

FIG. 2 illustrates a stylized, simplified cross-sectional view of a semiconductor device 100 after a second stage of manufacture, in accordance with embodiments herein;

FIG. 3 illustrates a stylized, simplified cross-sectional view of a semiconductor device 100 after a third stage of manufacture, in accordance with embodiments herein;

FIG. 4 illustrates a stylized, simplified cross-sectional view of a semiconductor device 100 after a fourth stage of manufacture, in accordance with embodiments herein;

FIG. 5 illustrates a stylized, simplified cross-sectional view of a semiconductor device 100 after a fifth stage of manufacture, in accordance with embodiments herein;

FIG. 6 illustrates a flowchart depiction of a method for manufacturing a device, in accordance with embodiments herein; and

FIG. 7 illustrates a stylized depiction of a system for fabricating a semiconductor device, in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached Figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for semiconductor devices comprising gates of different widths with substantially uniform gate metal heights.

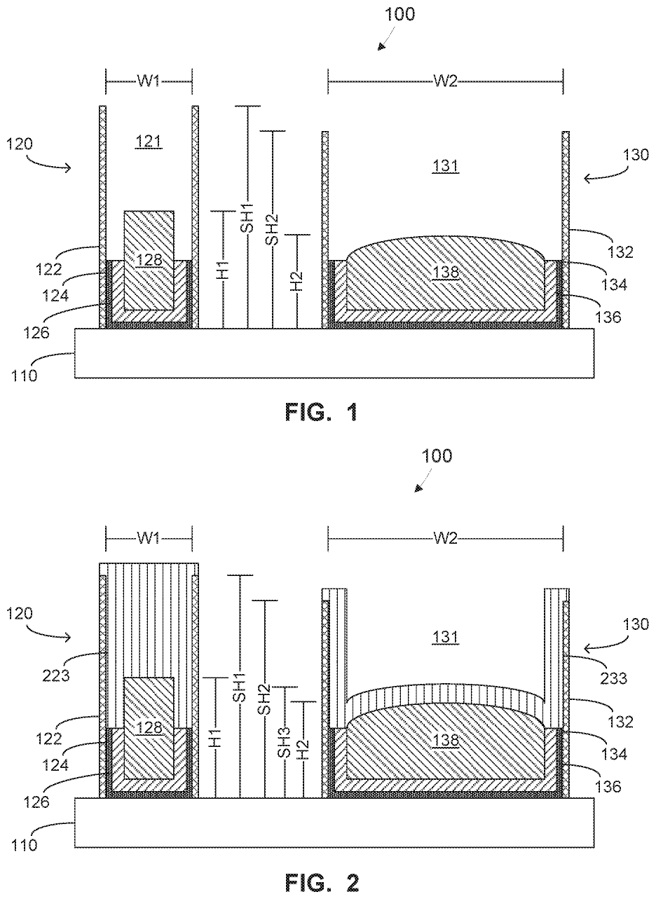

Turning now to FIG. 1, a stylized, simplified cross-sectional view of a semiconductor device 100 after a first stage of manufacture, in accordance with embodiments herein, is depicted. The semiconductor device 100 comprises a substrate 110, on which are formed two gates, a first gate 120 and a second gate 130. Each gate comprises a work function metal (WFM) 124 or 134; a liner 126 or 136; and a gate metal 128 or 138. Herein, the work function metal 124, the liner 126, and the gate metal 128 of the first gate 120 may be termed the first work function metal 124, the first liner 126, and the first gate metal 128. Similarly, the work function metal 134, the liner 136, and the gate metal 138 of the second gate 130 may be termed the second work function metal 134, the second liner 136, and the second gate metal 138.

The first gate metal 128 has a first height above the substrate 110 of H1, and the second gate metal 138 has a second height above the substrate 110 of H2. The first height H1 is above the height of the first work function metal 124. Similarly, the second height H2 is above the height of the second work function metal 134. The first height is greater than the second height, i.e., H1>H2.

The first gate 120 also comprises a first spacer 122 on the sides of the first gate 120. The first spacer 122 has a first spacer height SH1 greater than the first height H1. Accordingly, between the first spacer 122 on the sides of the first gate 120 and above the first WFM 124, the first liner 126, and the first gate metal 128 is defined a first region 121. Similarly, the second gate 130 also comprises a second spacer 132 on the sides of the second gate 130. The second spacer 132 has a second spacer height SH2 greater than the second height H2. Accordingly, between the second spacer 132 on the sides of the second gate 130 and above the second WFM 134, the second liner 136, and the second gate metal 138 is defined a second region 131.

The first spacer 122 and the second spacer 132 also define the widths of the first gate 120 (width W1) and the second gate 130 (width W2). The width of the second gate 130 is greater than the width of the first gate 120, i.e., W2>W1.

The various structures 120, 122, 124, 126, 128, 132, 134, 136, and 138 depicted in FIG. 1 may be formed from materials known to the person of ordinary skill in the art and by the use of known techniques. For example, the substrate 120 may comprise bulk silicon, silicon-on-insulator, or other materials. The first and second WFMs 124 and 134 may independently comprise N-type work function metals or P-type work function metals. In one embodiment, the first WFM 124 and the second WFM 134 both comprise an N-type work function metal.

In one embodiment, the first liner 126 and the second liner 136 both comprise titanium nitride.

In one embodiment, the first spacer 122 and the second spacer 132 both comprise a low-k dielectric spacer.

In one embodiment, the first gate metal 128 and the second gate metal 138 may be formed by overfilling regions 121 and 131 with metal, e.g., tungsten; performing chemical-mechanical polishing (CMP) to reduce the tops of the metal to no higher than the first and second spacers 122, 132; and recessing the metal to yield the formations depicted in FIG. 1.

Although FIG. 1 depicts only one narrow gate (first gate 120) and one wide gate (second gate 130), the semiconductor device 100 may comprise a plurality of first gates 120 and/or a plurality of second gates 130.

Also, FIG. 1 and subsequent figures omit other features of semiconductor device 100 for the sake of brevity. The person of ordinary skill in the art will understand that the semiconductor device 100 may comprise additional structures than those shown and still be encompassed by the present disclosure and claims.

FIG. 2 illustrates a stylized, simplified cross-sectional view of a semiconductor device 100 after a second stage of manufacture, in accordance with embodiments herein. In the second stage of manufacture, a third spacer material 223, 233 is deposited on the semiconductor device 100. The deposition fills the first region 121 previously shown in FIG. 1 between the first spacer 122 on the sides of the first gate 120 and above the first gate metal 128 with a third spacer material 223 up to at least the first spacer height SH1. On the other hand, the deposition conformally deposits the third spacer material 233 in the second region 131 between the second spacer 132 on the sides of the second gate 130, and on a top of the second gate metal 138 up to a third spacer material height SH3 below the second spacer height SH2. In other words, the third spacer material 223 pinches off the first gate 120 above the first gate metal 128, and does not pinch off the second gate 130 above the second gate metal 138. Part of the second region 131 remains unfilled whereas the entire first region 121 is filled.

The third spacer material 223, 233 may comprise any material known to the person of ordinary skill in the art. In one embodiment, the third spacer material 223, 233 may comprise silicon nitride (SiN). In another embodiment, the third spacer material 223, 233 may form an etch stop layer (ESL).

Deposition of the third spacer material 223, 233 may involve any known technique. In one embodiment, the deposition process conditions are selected such that filling the first region 121 with the third spacer material 223 and depositing conformally the third spacer material 233 in the second region 131 may be performed simultaneously. In another embodiment, one of the first gate 120 and the second gate 130 may be masked and the third spacer material 223 or 233 deposited in the first or second region 121 or 131 of the unmasked gate, followed by unmasking, masking the other gate, and depositing the third spacer material 223 or 233 in the newly-unmasked gate.

FIG. 3 illustrates a stylized, simplified cross-sectional view of a semiconductor device 100 after a third stage of manufacture, in accordance with embodiments herein. In the third stage of manufacture, the third spacer material 223, 233 is partially removed from both the first gate 120 and the second gate 130. This partial removal process involves removing the third spacer material 233 (formerly shown in FIG. 2) from the top of the second gate metal 138. As shown, this partial removal process retains much of the third spacer material on the inner walls of the second spacer 132, yielding third spacer material 333 in the second gate 130. Also as shown, this partial removal process retains sufficient of the third spacer material 223 (previously shown in FIG. 2) over the first gate metal 128 such that the first gate metal 128 remains covered by a third spacer material 323. However, it is expected that the top of the third spacer material 323 will be below the first spacer height SH1, thereby recreating the first region 121.

Process conditions for the partial removal of the third spacer material 223, 233 may be routinely selected by the person of ordinary skill in the art having the benefit of the present disclosure and need not be discussed in detail.

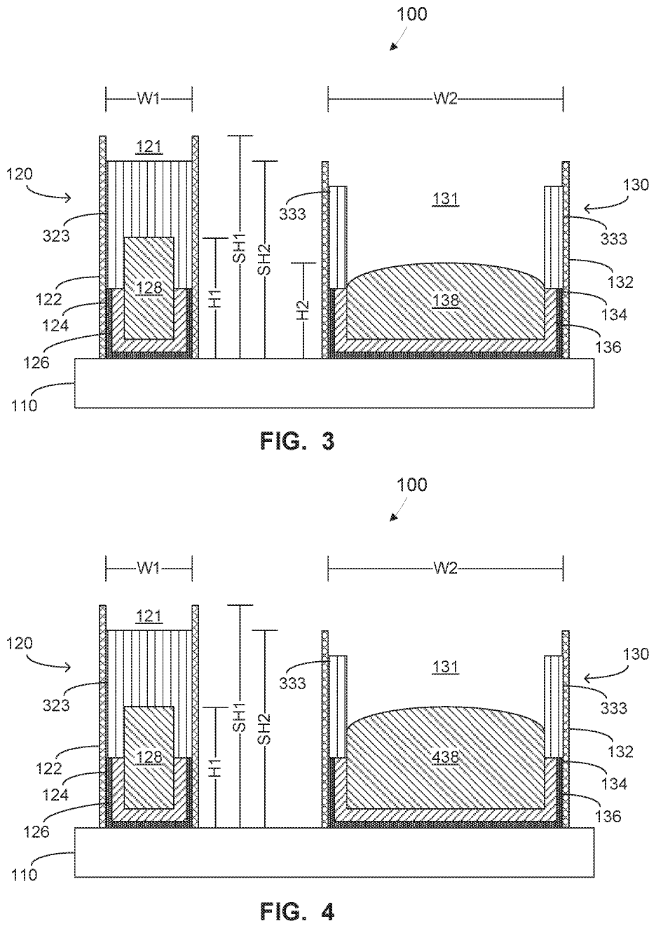

FIG. 4 illustrates a stylized, simplified cross-sectional view of a semiconductor device 100 after a fourth stage of manufacture, in accordance with embodiments herein. In the fourth stage of manufacture, metal is added to the second gate metal 138, thereby raising the top of the second gate metal 438 to about the first height H1. In other words, the first gate metal 128 and the second gate metal 438 may have substantially the same height, which may impart process efficiencies in subsequent processing steps and/or improved performance of a final semiconductor device 100 comprising the first gate 120 and the second gate 130.

Techniques for selective growth of a metal on the second gate metal 138 may be routinely selected by the person of ordinary skill in the art having the benefit of the present disclosure and need not be discussed in detail.

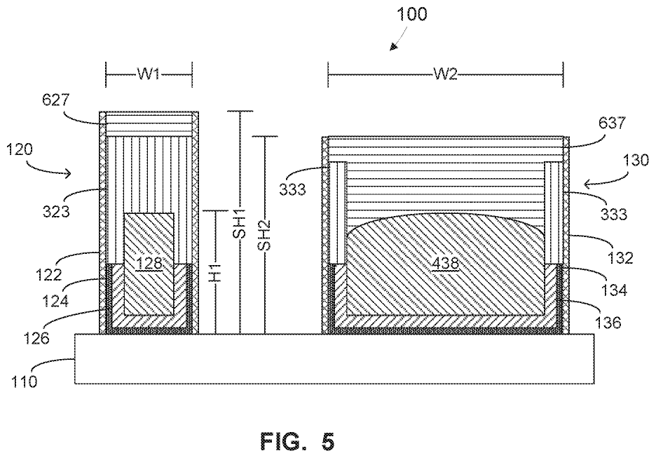

FIG. 5 illustrates a stylized, simplified cross-sectional view of a semiconductor device 100 after a fifth stage of manufacture, in accordance with embodiments herein. In the fifth stage of manufacture, the first region 121 and the second region 131 are filled with a cap spacer 627, 637. Filling with the cap spacer 627, 637 may involve overfilling the first region 121 and the second region 131 with the cap spacer 627, 637, followed by CMP to reduce the heights of the cap spacer 627, 637 to SH1 and SH2, respectively.

The cap spacer 627, 637 may comprise any appropriate material. In one embodiment, the cap spacer 627, 637 comprises SiN. Alternatively or in addition, the cap spacer 627, 637 may comprise the third spacer material 323, 333.

Thereafter, one or more additional processes known to the person of ordinary skill in the art (not shown) may be performed to produce a final product comprising the structure of FIG. 5. For example, the cap spacer 627, 637 may be sacrificed and other desired materials (e.g., dielectric layers, gate contacts, etc.) may be formed over the gate metal 128, 428.

In one embodiment, as shown in FIG. 5, the present disclosure relates to a semiconductor device 100, comprising:

a first gate 120 having a first width W1 and comprising a first work function metal 124; a first liner 126 disposed over the first work function metal 124; a first gate metal 128 over the first liner 126 and having a first height H1 above the height of the first work function metal 124; a first spacer 122 on the sides of the first gate 120 and having a first spacer height SH1 greater than the first height H1; and a first pinch-off spacer 323 over the first WFM 124, the first liner 126, and the first gate metal 128 to above the first height H1 and below the first spacer height SH1; and

a second gate 130 having a second width W2 greater than the first width W1, and comprising a second work function metal 134; a second liner 136 disposed over the second WFM 134; a second gate metal 438 over the second liner 136 and having substantially the first height H1; a second spacer 132 on the sides of the second gate 130 and having a second spacer height SH2 greater than the first height H1; and a first conformal spacer 333 over the second WFM 134 and the second liner 136.

In one embodiment, the first liner 126 and the second liner 136 comprise titanium nitride.

In one embodiment, the first pinch-off spacer 323 and the first conformal spacer 33 comprise SiN.

In one embodiment, the semiconductor device 100 further comprises a first cap spacer 627 above the first pinch-off spacer 323, up to the first spacer height SH1; and a second cap spacer 637 above the second gate metal 438 and adjacent the first conformal spacer 333, up to the second spacer height SH2.

In one embodiment, the first cap spacer 627 comprises SiN.

In one embodiment, the second cap spacer 637 comprises SiN.

In one embodiment, the first cap spacer 627, the second cap spacer 637, the first pinch-off spacer 323, and the first conformal spacer 333 comprise the same spacer material.

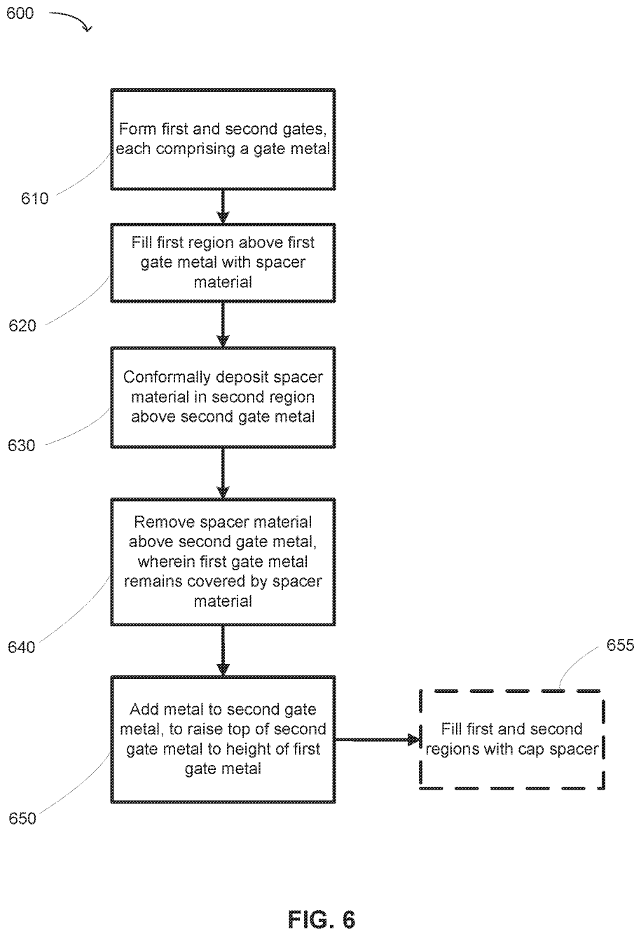

FIG. 6 illustrates a flowchart depiction of a method 600 for manufacturing a device, in accordance with embodiments herein. The method 600 comprises forming (at 610) a first gate having a first width and comprising a first work function metal; a first liner disposed over the first liner; a first gate metal over the first liner and having a first height above the height of the first work function metal; and a first spacer on the sides of the first gate and having a first spacer height greater than the first height; and a second gate having a second width and comprising a second work function metal; a second liner disposed over the second liner; and a second gate metal over the second liner and having a second height, wherein the first width is less than the second width and the first height is greater than the second height; and a second spacer on the sides of the second gate and having a second spacer height greater than the second height.

In one embodiment, the first liner and the second liner comprise titanium nitride.

The method 600 additionally comprises filling (at 620) a first region between the first spacer on the sides of the first gate and above the first gate metal with a third spacer material up to at least the first spacer height. The method 600 further comprises depositing conformally (at 630) the third spacer material in a second region between the second spacer on the sides of the second gate, and on a top of the second gate metal up to a third spacer material height below the second spacer height. The filling (at 620) and the depositing conformally (at 630) may be performed sequentially or simultaneously.

In one embodiment, the third spacer material comprises silicon nitride (SiN).

The method 600 also comprises removing (at 640) the third spacer material from the top of the second gate metal, wherein the first gate metal remains covered by the third spacer material.

The method 600 further comprises adding (at 650) metal to the second gate metal, thereby raising the top of the second gate metal to about the first height.

In one embodiment, the method 600 further comprises filling (at 655) the first region and the second region with a cap spacer. In one embodiment, the cap spacer comprises SiN. Alternatively or in addition, the cap spacer may comprise the third spacer material.

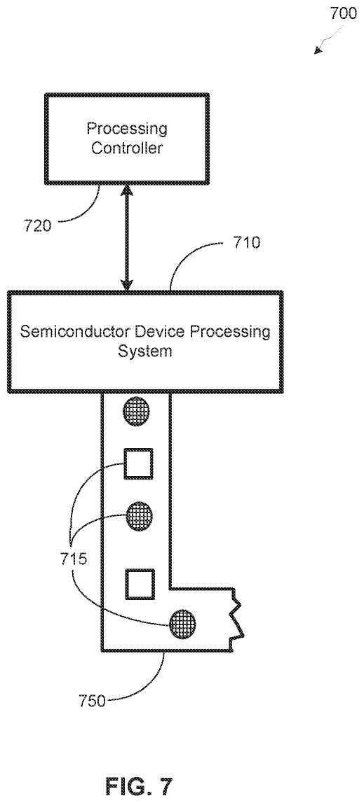

Turning now to FIG. 7, a stylized depiction of a system for fabricating a semiconductor device, in accordance with embodiments herein, is illustrated. The system 700 provides for semiconductor devices comprising gates of different widths with substantially similar gate metal heights.

The system 700 of FIG. 7 may comprise a semiconductor device processing system 710 and a processing controller 720.

The semiconductor device processing system 710 may comprise various processing tools, such as etch process stations, photolithography process stations, oxide deposition process stations, CMP process stations, epitaxy (EPI) process stations, etc. The semiconductor device processing system 710 may also comprise one or more metrology tools. One or more of the processing steps performed by the processing system 710 may be controlled by the processing controller 720. The processing controller 720 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc. Generally, the processing controller 720 may communicate to the semiconductor device processing system 710 via an interface.

The semiconductor device processing system 710 may produce semiconductor devices on a medium, such as silicon wafers. More particularly, the semiconductor device processing system 710 may produce semiconductor devices as described above.

The production of integrated circuits by the device processing system 710 may be based upon the circuit designs provided by the integrated circuits design unit 740. The processing system 710 may provide processed integrated circuits/devices 77 on a transport mechanism 750, such as a conveyor system. In some embodiments, the conveyor system may be sophisticated clean room transport systems that are capable of transporting semiconductor wafers.

In some embodiments, the items labeled “715” may represent individual wafers, and in other embodiments, the items 715 may represent a group of semiconductor wafers, e.g., a “lot” of semiconductor wafers. The semiconductor device 715 may comprise a transistor, a capacitor, a resistor, a memory cell, a processor, and/or the like.

The system 700 may be capable of performing analysis and manufacturing of various products involving various technologies. For example, the system 700 may design and manufacturing-data for manufacturing devices of CMOS technology, Flash technology, BiCMOS technology, power devices, memory devices (e.g., DRAM devices), NAND memory devices, and/or various other semiconductor technologies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a first gate having a first width and comprising a first gate metal having a first height; and first spacers on the sides of the first gate and having a first spacer height greater than the first height;
forming a second gate having a second width and comprising a second gate metal having a second height, wherein the first width is less than the second width and the first height is greater than the second height; and second spacers on the sides of the second gate and having a second spacer height greater than the second height;
filling a first region between the first spacers on the sides of the first gate and above the first gate metal with a third spacer material;
depositing conformally the third spacer material in a second region between the second spacers on the sides of the second gate, and on a top of the second gate metal;
removing the third spacer material from the top of the second gate metal, wherein the first gate metal remains covered by the third spacer material; and
adding metal to the second gate metal, thereby raising the top of the second gate metal to about the first height.

2. The method of claim 1, further comprising:
filling the first region and the second region with a cap spacer.

3. The method of claim 1, wherein the first gate comprises a first liner disposed below and to the sides of the first gate metal, the second gate comprises a second liner disposed below and to the sides of the second gate metal, and the first liner and the second liner comprise titanium nitride.

4. The method of claim 1, wherein the third spacer material comprises silicon nitride (SiN).

5. The method of claim 2, wherein the cap spacer comprises SiN.

6. The method of claim 1, wherein the first gate metal and the second gate metal comprise tungsten.

7. The method of claim 1, wherein the third spacer material is an etch stop layer (ESL).

8. A semiconductor device, comprising:
a first gate having a first width and comprising a first work function metal (WFM); a first liner disposed over the first WFM; a first gate metal over the first liner and having a first height above the height of the first work function metal; a first spacer on the sides of the first gate and having a first spacer height greater than the first height; a first pinch-off spacer over the first WFM, the first liner, and the first gate metal to above the first height and below the first spacer height; and
a second gate having a second width greater than the first width, and comprising a second WFM; a second liner disposed over the second WFM; a second gate metal over the second liner and having substantially the first height; a second spacer on the sides of the second gate and having a second spacer height greater than the first height; and a first conformal spacer over the second WFM and the second liner.

9. The semiconductor device of claim 8, wherein the first liner and the second liner comprise titanium nitride.

10. The semiconductor device of claim 8, wherein the first pinch-off spacer and the first conformal spacer comprise SiN.

11. The semiconductor device of claim 8, further comprising:
a first cap spacer above the first pinch-off spacer, up to the first spacer height; and
a second cap spacer above the second gate metal and adjacent the first conformal spacer, up to the second spacer height.

12. The semiconductor device of claim 10, wherein the first cap spacer comprises SiN.

13. The semiconductor device of claim 10, wherein the second cap spacer comprises SiN.

14. The semiconductor device of claim 8, wherein the first gate metal and the second gate metal comprise tungsten.

15. A system, comprising:
a semiconductor device processing system to manufacture a semiconductor device; and
a processing controller operatively coupled to the semiconductor device processing system, the processing controller configured to control an operation of the semiconductor device processing system;
wherein the semiconductor device processing system is adapted to:
form a first gate having a first width and comprising a first gate metal having a first height; and first spacers on the sides of the first gate and having a first spacer height greater than the first height;
form a second gate having a second width and comprising a second gate metal having a second height, wherein the first width is less than the second width and the first height is greater than the second height; and second spacers on the sides of the second gate and having a second spacer height greater than the second height;
fill a first region between the first spacers on the sides of the first gate and above the first gate metal with a third spacer material;
conformally deposit the third spacer material in a second region between the second spacers on the sides of the second gate, and on a top of the second gate metal;
remove the third spacer material from the top of the second gate metal, wherein the first gate metal remains covered by the third spacer material;
add metal to the second gate metal, thereby raising the top of the second gate metal to about the first height.

16. The system of claim 15, wherein the semiconductor device processing system is further adapted to:
fill the first region and the second region with a cap spacer.

17. The system of claim 15, wherein the semiconductor device processing system is adapted to form a first liner in the first gate before forming the first gate metal, form a second liner in the second gate before forming the second gate metal, and form the first liner and the second liner from titanium nitride.

18. The system of claim 15, wherein the semiconductor device processing system is adapted to form the third spacer material from silicon nitride (SiN).

19. The system of claim 16, wherein the semiconductor device processing system is adapted to form the cap spacer from SiN.

20. The system of claim 15, wherein the semiconductor device processing system is adapted to form the first gate metal and the second gate metal from tungsten.
